(19) United States
(12) Patent Application Publication
(10) Pub. No.: US 2014/0063772 A1
(43) Pub. Date: Mar. 6, 2014

(54) ELECTRONIC APPARATUS

(71) Applicant: SONY CORPORATION, Tokyo (JP)

(72) Inventors: Hideaki Kurachi, Kanagawa (JP); Kouichi Hiroyoshi, Nagano (JP); Mitsuhiro Uehara, Tokyo (JP)

(73) Assignee: SONY CORPORATION, Tokyo (JP)

(21) Appl. No.: 13/973,293

(22) Filed: Aug. 22, 2013

(30) Foreign Application Priority Data
Aug. 29, 2012 (JP) 2012-188809

(51) Int. Cl. H05K 7/16

(52) U.S. Cl. CPC H05K 7/16
USPC 361/809

(57) ABSTRACT

An electronic apparatus includes a main body having a first surface having a display surface, a second surface opposite to the first surface, and a first support disposed between the first surface and the second surface being capable of contacting with a put-on surface; a stand member attached to the main body having a second support being capable of contacting with the put-on surface; and a hinge unit having a hinge rotatably supporting the stand member against the main body between a first rotational position for standing up the main body on the put-on surface and a second rotational position for laying the main body over the put-on surface, and an elastic member disposed at the hinge for adding a rotational force from a second rotational position side to a first rotational position side.

### BACKGROUND

The present disclosure relates to an electronic apparatus having a stand.

In general, a personal computer display includes a stand for supporting a display surface tilted at any angle to an upper surface of a desk. For example, Japanese Patent Application Laid-open No. 2005-31555 describes a display apparatus including a stand disposed at a rear surface of a display apparatus case for standing up the case to a put-on surface. Japanese Patent Application Laid-open No. 2009-47742 describes a display apparatus including a main body stand, an arm standing from the stand and pivotally linked to the main body stand, and a display pivotally liked to the arm.

### SUMMARY

There is a need for a display apparatus having a configuration that a tilt angle of a display surface is prevented from easily changing by an unintentional external force, but can be easily changed by a user.

It is desirable to provide a display apparatus capable of easily adjusting a display surface at any angle and stably keeping a tilt angle.

According to an embodiment of the present technology, there is provided an electronic apparatus including a main body, a stand member, and a hinge unit.

The main body has a first surface having a display surface, a second surface opposite to the first surface, and a first support disposed between the first surface and the second surface being capable of contacting with a put-on surface.

The stand member attached to the main body has a second support being capable of contacting with the put-on surface.

The hinge unit has a hinge and an elastic member. The hinge rotatably supports the stand member against the main body between a first rotational position for standing up the main body on the put-on surface and a second rotational position for laying the main body over the put-on surface. The elastic member is disposed at the hinge and adds a rotational force to the stand member from a second rotational position side to a first rotational position side.

In the electronic apparatus, the display surface is supported by the first support disposed at the main body and the second support disposed at the stand member at a predetermined tilt angle against the put-on surface. At this time, a rotational force from the first rotational position side to the second rotational position side by a main body's own weight acts on the stand member. On the other hand, a rotational force from the second rotational position side to the first rotational position side acts on the stand member by the elastic member of the hinge unit.

Accordingly, by appropriately adjusting the rotational force, the angle of the display surface can be continuously changed, and the tilt angle of the display surface can be stably kept. As the own weight of the main body and the rotational force by the hinge unit can be utilized, the operational force for manually adjusting the tilt angle of the display surface can be decreased, resulting in improved handleability.

The hinge unit further may have an adjustment mechanism being capable of setting the rotational force. In this case, the adjustment mechanism may be set to balance with a rotational moment by the own weight of the main body using the first support as a center.

As the stand member follows a position change of the main body, a separate angle adjustment of the stand member is unnecessary.

The adjustment mechanism may regulate the rotational force so that a relative position of the stand member against the main body is kept.

The main body can be translocated to other put-on surface while the tilt angle of the display surface is kept.

The adjustment mechanism may cancel a regulation of a rotational force in a predetermined angle range from the second rotational position to the first rotational position.

As a predetermined space is formed between the second surface of the main body and the stand member, pivot operability to the first rotational position side can be improved after the stand member is rotated to the second rotational position.

The elastic member may have a torsion spring.

As the elastic member is composed of the torsion spring, the rotational force proportional to a rotational operation amount of the stand member can be generated on the stand member in a direction opposite to a rotational direction.

The hinge unit may be disposed at the second surface.

In this way, the hinge unit may be less visible at the display surface, whereby designability of the electronic apparatus can be enhanced.

The hinge unit may be disposed nearer the first support side than a center position of the main body in a height direction.

It is thereby possible to prevent the second support of the stand member from protruding outside a peripheral of the main body when the stand member is rotated to the second rotational position, resulting in a compact electronic apparatus for storage.

The second surface may have a convex part that is protruded from the main body outwardly. In this case, the convex part has a third support being capable of contacting with the put-on surface when the stand member is rotated to the second rotational position.

In the electronic apparatus having the above-described configuration, the third support is contacted with the put-on surface when the display surface is pushed down to the put-on surface. At this time, the third support may be configured to support the main body instead of the first support.

The stand member may have an arm that is bent along a circumference of the convex part at the second rotational position. In this way, the main body and the stand member are well integrated, whereby designability is enhanced, and the electronic apparatus can be downsized and thinned.

The convex part may have a surrounding part that is tapered to a center top of the convex part. In this case, the arm faces to the surrounding part and has a tapered inner peripheral part corresponding to the surrounding part.

In this way, it is possible to dispose the stand member adjacent to the surrounding part of the convex part in the second rotational position.

The first support is disposed at the surrounding part of the main body, and the surrounding part is formed of a flat or curve tilted surface.

It is thereby possible to prevent the bottom of the display surface from floating above the put-on surface when the display surface is moved from a standing position against the put-on surface to a tilt position against the put-on surface. In this way, a decrease in visibility or operability of the display surface can be inhibited.

It is desirable to provide a display apparatus capable of easily adjusting a display surface at any angle and stably holding a tilt angle.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a perspective view looking from a front side of an electronic apparatus according to an embodiment of the present technology;

FIG. 2 is a perspective view looking from a back side of the electronic apparatus;

FIG. 3 is a side view showing that the electronic apparatus is stood up against a put-on surface;

FIG. 4 is a side view showing the electronic apparatus laid on the put-on surface;

FIG. 5 is a front view showing a relationship between a stand member and a hinge unit in the electronic apparatus;

FIG. 6 is an enlarged front view of the hinge unit;

FIG. 7 is a side view of the hinge unit;

FIG. 8 is a sectional view of FIG. 6 along a [A]-[A] line direction;

FIGS. 9A to 9C are each a schematic side view illustrating an action example of the electronic apparatus when the electronic apparatus is changed in a position from a standing position to a laid-on position;

FIGS. 10A to 10C are each a schematic side view illustrating an action example of the electronic apparatus when the electronic apparatus is changed in a position from a laid-on position to a standing position;

FIGS. 11A to 11D are each a schematic side view illustrating another action example of the electronic apparatus when the electronic apparatus is put on a put-on surface in a standing position;

FIGS. 12A to 12C are each a schematic side view illustrating another action example of the electronic apparatus when the electronic apparatus is changed in a position from a standing position to a laid-on position; and

FIG. 13 is an enlarged view of a main part of the electronic apparatus for illustrating one action example.

### DETAILED DESCRIPTION OF EMBODIMENTS

Hereinafter, an embodiment of the present disclosure will be described with reference to the drawings.

### [Whole Configuration of Electronic Apparatus]

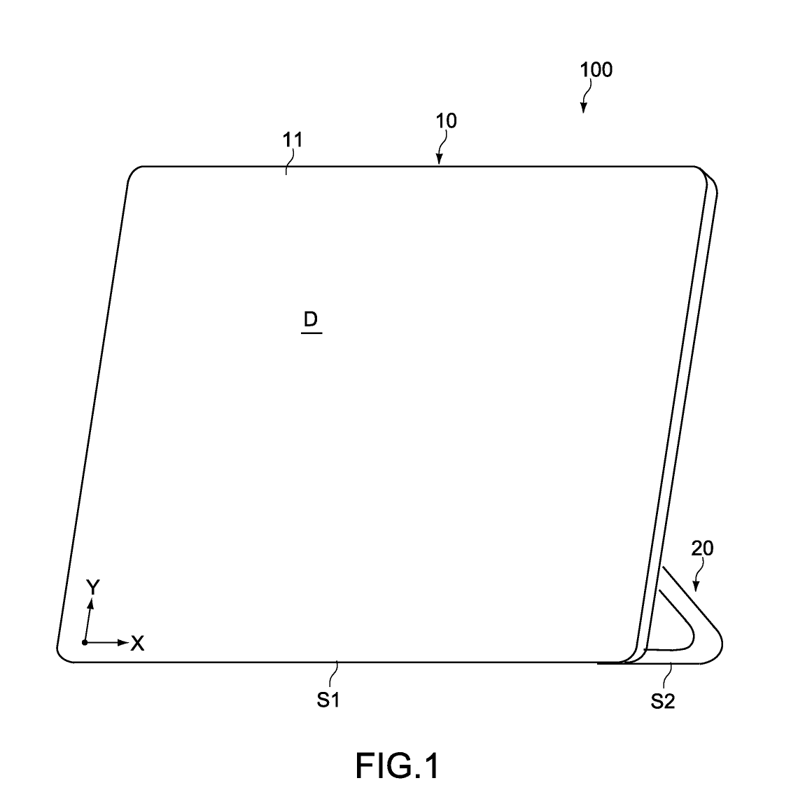

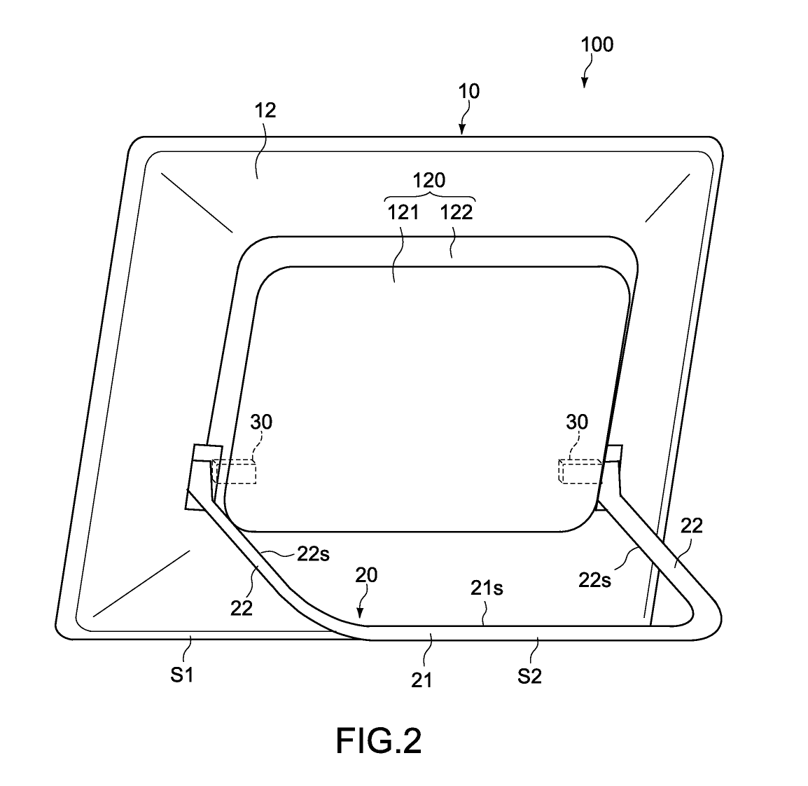

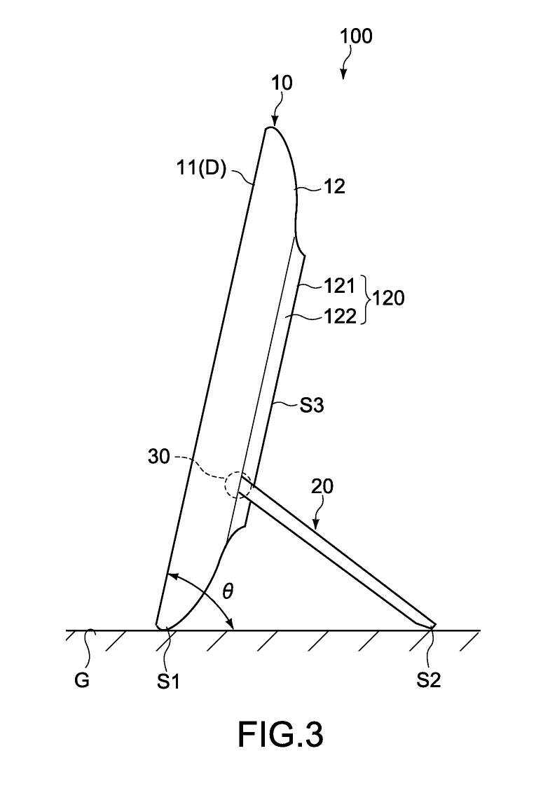

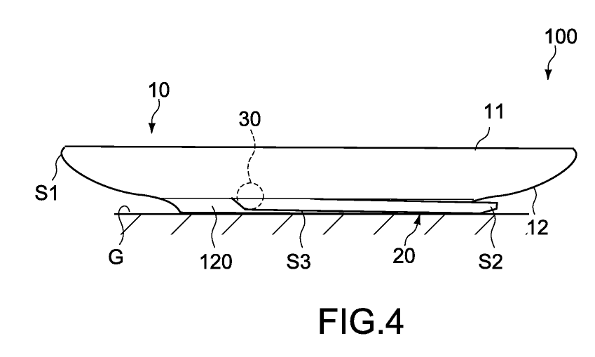

FIGS. 1 to 4 show a configuration of an electronic apparatus according to an embodiment of the present technology. FIG. 1 is a perspective view looking from a front side, FIG. 2 is a perspective view looking from a back side, FIG. 3 is a side view showing that the electronic apparatus is stood up against a put-on surface, and FIG. 4 is a side view showing the electronic apparatus laid on the put-on surface. An electronic apparatus 100 according to this embodiment is configured of an information processing apparatus having a built-in display, or a personal computer, for example, which is not limited thereto, and may be a general display, a monitor or the like.

The display apparatus 100 according to this embodiment includes a main body 10, a stand member 20, and a hinge unit 30.

### (Main Body)

The main body 10 has a front surface 11 having a display surface D and a back surface 12 at an opposite side thereof, and has an almost sheet-like shape as a whole. The display surface D is composed of a liquid crystal display, an organic EL display or the like, for example, and is formed of a rectangular flat surface having a horizontal (transverse) direction in an X axis direction and a vertical (longitudinal) direction in an Y axis direction. The display surface D has a touch panel, which allows a plurality of users to perform input operations.

The main body 10 has built-in hardware parts for configuring a computer such as a CPU (Central Processing Unit)/MPU (Micro Processing Unit), a main memory, a memory device and a mother board. Examples of the memory device include an HDD (Hard Disk Drive) and an SSD (Solid State Drive).

The back surface 12 of the main body 10 has an almost shallow pan shape. The back surface 12 of the main body 10 has a convex part 120 that is protruded from the main body 10 outwardly. The convex part 120 is formed of a stereoscopic pedestal disposed at an almost center of the back surface 12, which has a flat top 121 formed atop of the pedestal and a surrounding part 122 that is tapered to a center of the flat top 121. The convex part 120 may include a circuit board, a battery unit etc. on which a variety of driving circuits and control circuits for driving the main body 10 are mounted.

On the back surface of the main body 10, a variety of switches such as a power button, a plurality of connection modules electrically connectable to external devices, etc. (not shown) are disposed at an area excluding the convex part 120. Examples of the external devices include electronic devices such as a printer, a monitor, a projector, a router, a hub, a personal computer, a camera, a video camera and a mobile phone. Examples of the connection modules include connection ports or connecter jacks of a variety of modules such as a VGA (Video Graphics Array), a LAN (Local Area Network), an USB (Universal Serial Bus) and an HDMI (High-Definition Multimedia Interface).

The main body 10 has a first support S1 being capable of contacting with a put-on surface G. The first support S1 is formed on a straight line of the surrounding part at a bottom of the main body 10. The main body 10 is kept standing on the put-on surface G by allowing the first support S1 to be contacted with the put-on surface G to support the main body 10 by the stand member 20.

The surrounding part of the main body 10 having the first support S1 is formed of a flat or curve tilted surface. It is thereby possible to prevent the bottom of the display surface D from floating above the put-on surface G when the display surface D is moved from a standing position against the put-on surface G to a tilt position against the put-on surface G. In this way, a decrease in visibility or operability of the display surface D can be inhibited.

### (Stand Member)

The stand member 20 is attached to a back surface 12 side of the main body 10. The stand member 20 is used for assisting self-support of the main body 10 against the put-on surface G.

The stand member 20 can be continuously rotated such that the main body 10 is changed from the standing position tilted at a predetermined angle against the put-on surface G as shown in FIG. 3 to the laid-on position against the put-on surface G as shown in FIG. 4.

The stand member 20 is made of a metal material, for example, is almost parallel to the display surface D at a second rotational position as shown in FIG. 4, and has an arm that is bent along a circumference of the convex part 120. In this way, the main body 10 and the stand member 20 are well integrated, whereby designability is enhanced, and the electronic apparatus 100 can be downsized and thinned.

According to this embodiment, the stand member 20 is formed by bending an overall belt-shaped member at angle of almost 90 degrees in a predetermined position, and has a main arm 21 extending in parallel to an X axis direction of the display surface D and a pair of assistant arms 22 linked to both ends of the main arm 21. Each assistant arm 22 is pivotably attached to the back surface 12 of the main body 10 via the hinge unit 30.

The main arm 21 functions as a second support S2 being capable of contacting with the put-on surface G. The main arm 21 also functions as an operation part operated by a user's hand or finger to rotate the stand member 20.

In the laid-on position of the main body 10 against the put-on surface G, the convex part 120 of the main body 10 is contacted with the put-on surface G, and functions as a third support S3 for supporting the main body 10 instead of the first support S1.

Each arm 21, 22 of the stand member 20 is disposed facing to the surrounding part 122 of the convex part 120 in the second rotational position. In this embodiment, each arm 21, 22 has a tapered inner peripheral part 21s, 22s corresponding to the surrounding part 122 of the convex part 120. In this way, it is possible to dispose the stand member 20 adjacent to the surrounding part 122 of the convex part 120 in the second rotational position, thereby further improving integration between the stand member 20 and the convex part 120 in the second rotational position.

### (Hinge Unit)

The hinge unit 30 is connected between the main body 10 and the stand member 20. In this embodiment, the hinge unit 30 is disposed at the back surface 12 side of the main body 10. In this way, the hinge unit 30 is less visible at a display surface D side, whereby designability of the electronic apparatus 100 can be enhanced.

The hinge unit 30 rotatably supports the stand member 20 against the main body 10 between a first rotational position (FIG. 3) for standing up the main body 10 on the put-on surface G and a second rotational position (FIG. 4) for laying the main body 10 over the put-on surface G. In this embodiment, a maximum tilt angle θ of the display surface D against the put-on surface G is 75 degrees, and a minimum tilt angle is 0 degree.

In this embodiment, the hinge unit 30 is disposed nearer a first support S1 side than a center position of the main body 10 in a height direction. It is thereby possible to prevent the second support S2 of the stand member from protruding outside a peripheral of the main body 10 when the stand member 20 is rotated to the second rotational position, resulting in a compact electronic apparatus 100 for storage.

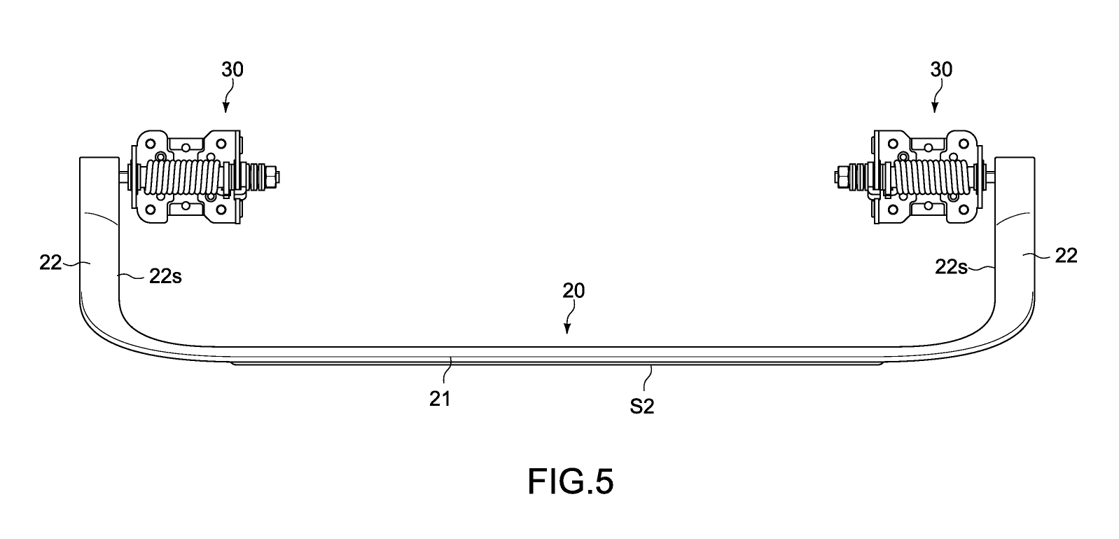

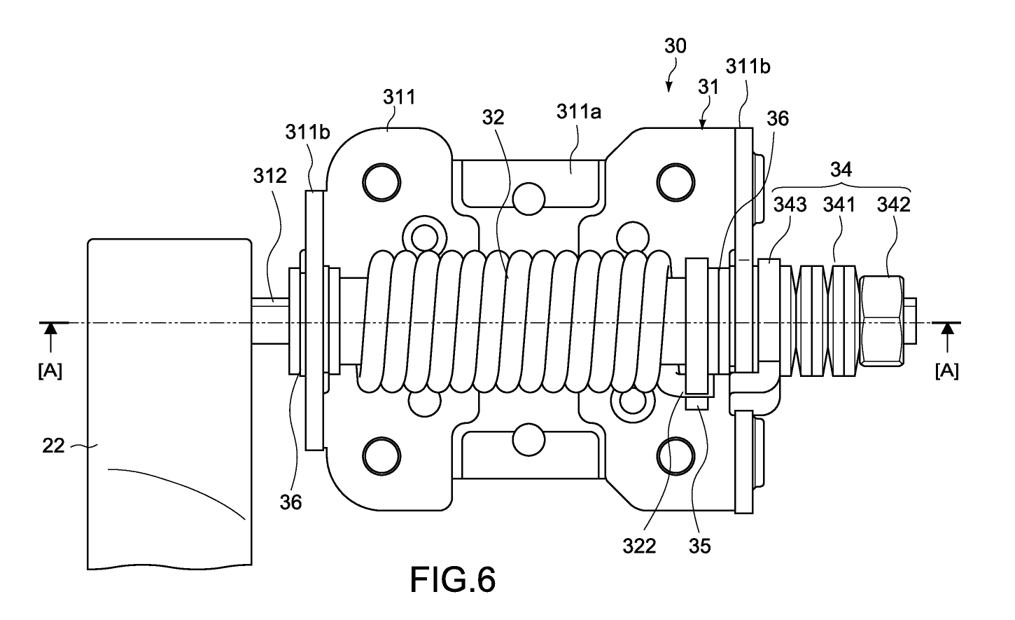

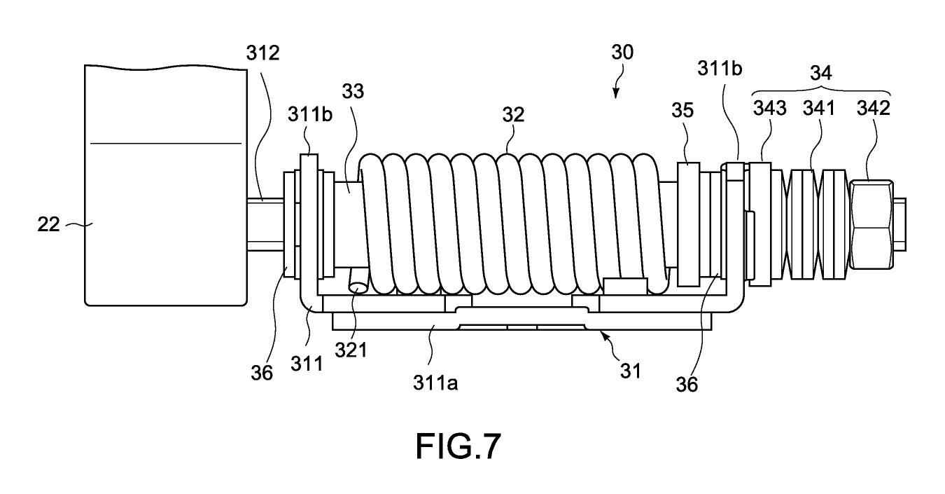

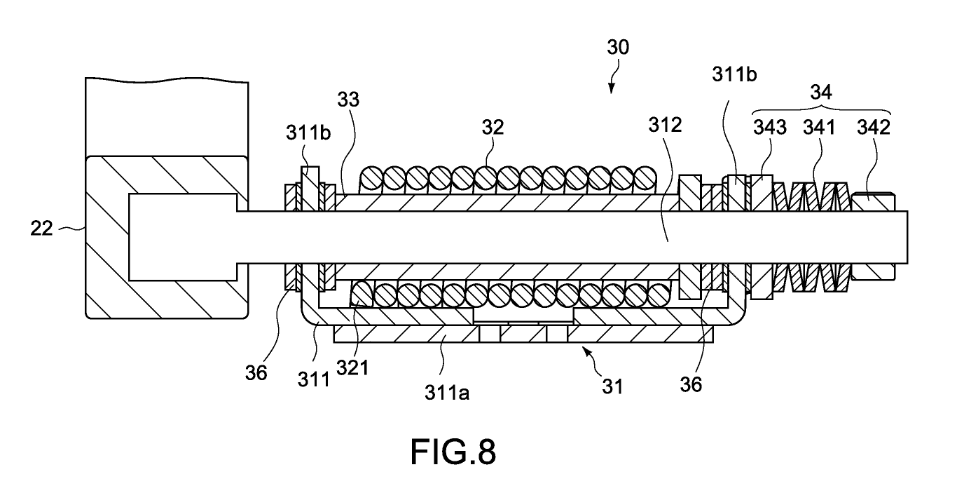

FIG. 5 is a front view showing a relationship between the stand member 20 and the hinge unit 30. FIG. 6 is an enlarged front view of the hinge unit 30. FIG. 7 is a side view of the hinge unit 30. FIG. 8 is a sectional view of FIG. 6 along a [A]-[A] line direction.

In this embodiment, there is a pair of hinge units 30 rotatably supports the stand member 20 against the main body 10. Each hinge unit 30 is attached to an each end of a pair of the assisting arms 22. The hinge units 30 are disposed facing each other inside the convex part 120 of the main body 10. It is thereby possible to hide the hinge units 30 from the outside, whereby designability of the electronic apparatus 100 can be enhanced.

Each hinge unit 30 has the same configuration, and includes a hinge 31, an elastic member 32 and an adjustment mechanism 34.

The hinge 31 has a bracket 311 and a hinge shaft 312. The bracket 311 has a fixture 311a that is fixed to the back surface 12 of the main body 10 via a plurality of screw members (not shown), and a pair of supports 311b that rotatably support the hinge shaft 312. The hinge shaft 312 is integrally fixed to the end of the assisting arm 22, and passes through each of a pair of the supports 311b.

The elastic member 32 is composed of a torsion spring, and is put around the hinge shaft 312 via a sleeve 33. The sleeve 33 is disposed between a pair of supports 311b, through which the hinge shaft 312 passes. On end 321 of the elastic member 32 is locked to the support 311b of the bracket 311, and the other end 322 is locked to a ring member 35 fixed to the hinge shaft 312.

The elastic member 32 generates an elastic force (a rotational force) for recovering the stand member 20 from the second rotational position side to the first rotational position side, when the stand member 20 is rotated from the first rotational position side as shown in FIG. 3 to the second rotational position side as shown in FIG. 4. As the elastic member 32 is composed of the torsion spring, the rotational force proportional to a rotational operation amount of the stand member 20 can be generated.

The adjustment mechanism 34 is for setting the rotational force by the above-described elastic member 32 to an appropriate magnitude. The adjustment mechanism 34 is disposed at an end side of the hinge shaft 312 passing through the bracket 311, and has a plurality of washers 341, a nut member 342, and a fixture ring 343.

A plurality of washers 341 is disposed between the nut member 342 and the fixture ring 343, and is composed of a metal or resin spring washers. The nut member 342 is screwed to the end of the hinge shaft 312. The fixture ring 343 is disposed around the hinge shaft 312, and is integrally fixed to the supports 311b of the bracket 311 to support the end side of the hinge shaft 312. In this way, depending on a fastening force of the nut member 342, a rotational friction force of the hinge shaft 312 is changed against the bracket 311. The greater the fastening force of the nut member 342 is, the more the rotational force of the stand member 20 attributable to the elastic force of the elastic member 32 is limited.

Other than those above, in the hinge unit 30, an appropriate amount of a lubricant such as grease is coated between the bracket 311 and the hinge shaft 312, and washers are put around the hinge shaft 312 at appropriate positions.

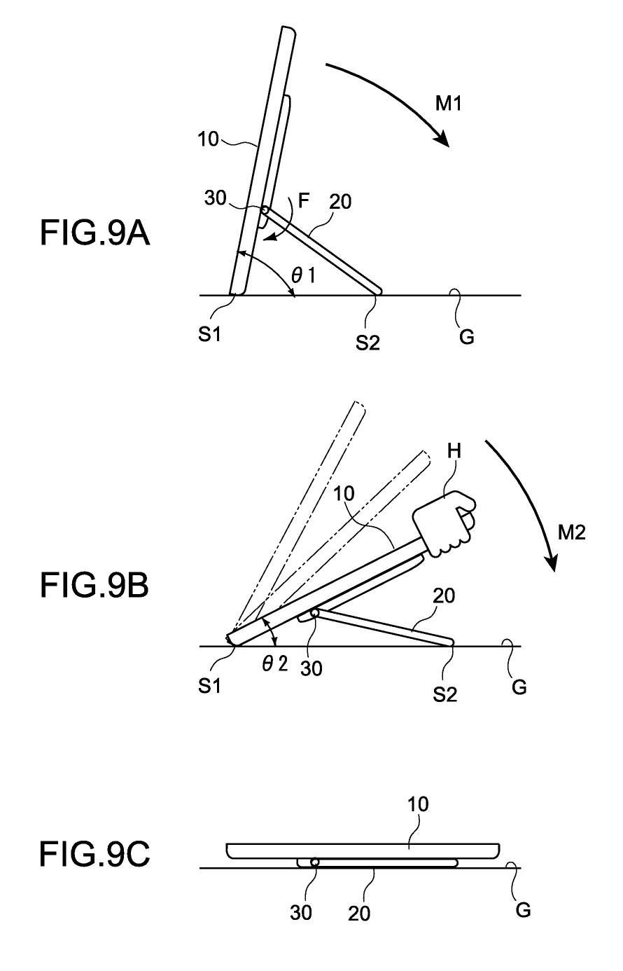

FIG. 9A is a schematic side view of the electronic apparatus 100 showing that the main body 10 is stood up and tilted at a predetermined angle (θ1) against the put-on surface G.

In this state, the stand member 20 is in the first rotational position against the main body 10, and the second support S2 is contacted with the put-on surface G, whereby the main body 10 keeps a standing position. At this time, a rotational moment M1 that pushes the main body 10 down to the back surface 12 side using the first support S1 as a fulcrum acts on the hinge unit 30. As a result, a rotational force F that keeps the stand member 20 to the first rotational position acts on the stand member 20 from the hinge unit 30.

According to this embodiment, in the adjustment mechanism 34, the rotational force F attributable to the elastic member 32 is set to balance with a rotational moment M1 by its own weight of the main body 10 using the first support S1 as a center. In other words, when the main body 10 is stood up and tilted at the predetermined angle against a put-on surface G side, the rotational force F is adjusted such that a force in a direction that the main body 10 is fallen to the put-on surface by its own weight can be canceled and the standing position of the main body 10 can be kept.

The rotational moment M1 is changed depending on a size of the angle θ1. The smaller the angle θ1 is, the greater the rotational moment M1 is. In other words, the smaller the angle θ1 is, the greater a rotational amount of the stand member 20 against the main body 10 is and the greater the rotational force F by the hinge unit 30 is. As a result, the main body 10 can keep its position at any tilt angle θ1. The rotational force F is set depending on the own weight of the main body 10, the size of the tilt angle θ1, and the like. In this embodiment, a weight of the main body 10 is about 5 kg, and a maximum value (θ) of the tilt angle θ1 is about 75 degrees.

FIGS. 9B and 9C show that the main unit 10 is pushed down to the put-on surface G side. In this time, a rotational moment M2 (M2>M1) where a push-down operation force by a user H to the main unit 10 is added to the rotational moment by its own weight of the main body 10 acts on the hinge unit 30. In this way, the rotational force F is relatively decreased and a position holding force of the main body 10 is loosened. By the push-down operation of the main body 10, the stand member 20 rotates in a counterclockwise direction in FIGS. 9B and 9C.

For example, as shown in FIG. 9B, when the push-down operation by the user H is canceled at an arbitrary tilt angle θ2 (θ2<θ1), the main body 10 keeps the position at the tilt angle θ2 by the rotational force F by the hinge unit 30. As shown in FIG. 9C, when the main body 10 is laid down to the put-on surface G, the rotational force F acting on the stand member 20 reach the maximum value, and the stand member 20 keeps the second rotational position by the own weight of the main body 10.

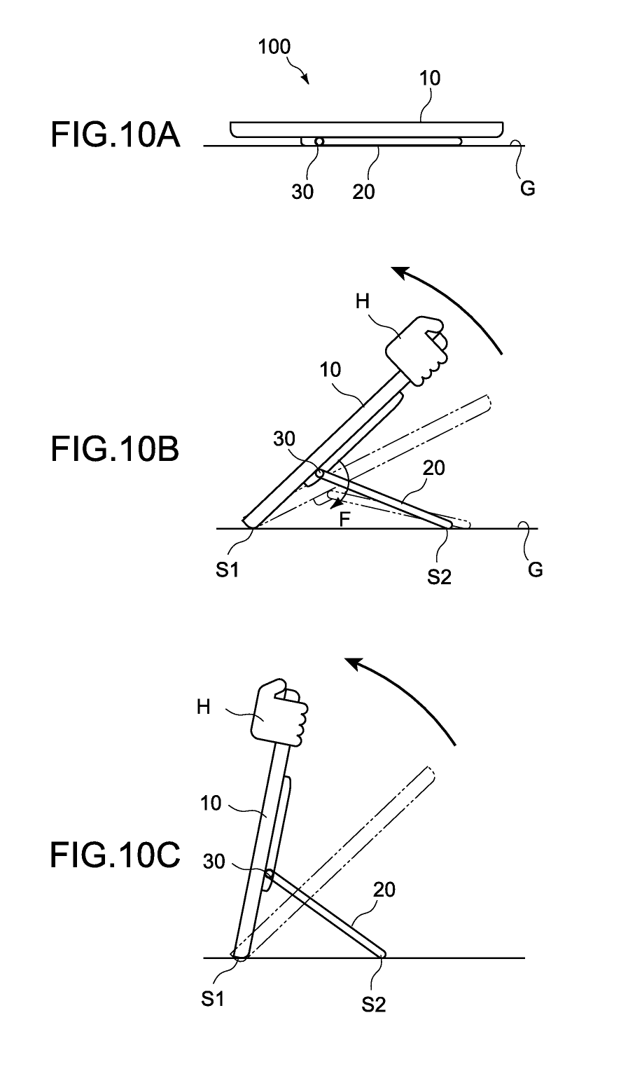

FIGS. 10A to 10C show a typical action example that the main body 10 is changed its position from the laid-on position to the standing position. When the user H raises the main body 10 using the first support S1 as the fulcrum, the own weight of the main body 10 does not act on the hinge unit and the rotational force F by the hinge unit 30 acts instead on the stand member 20. In this way, the stand member 20 rotates from the second rotational position to the first rotational position along with a raise of the main body 10 while the second support S2 is contacted with the put-on surface G.

In this case, the rotational force F acts on the main body 10 such that the main body 10 is stood up. The user H is assisted by the rotational force F, which leads to a decrease in the operational force for raising the main body 10. When the user H cancels a raise operation of the main unit 10, a tilt position of the main body 10 is kept at this point by the rotational force F by the hinge unit 30.

According to this embodiment, the angle of the display surface D can be continuously changed, and the tilt angle of the display surface D can be stably held. It is thereby possible to prevent the tilt angle of the display surface D from easily changing by an unintentional external force, and to easily change the tilt angle of the display surface D by the user.

Also, according to this embodiment, as the own weight of the main body 10 and the rotational force by the hinge unit 30 can be utilized, the operational force for manually adjusting the tilt angle of the display surface can be decreased. When the main unit 10 is relatively heavy, handleability is advantageously improved. In addition, as the angle of the stand member 20 is automatically changed along with the push-down operation or the raise operation against the main body 10, an angle adjustment of the stand member 20 is unnecessary, whereby operability is improved.

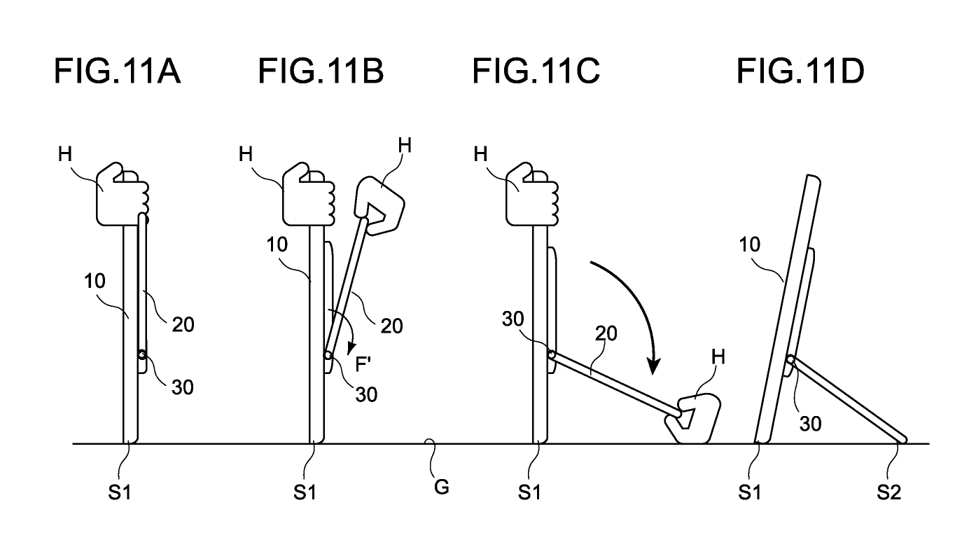

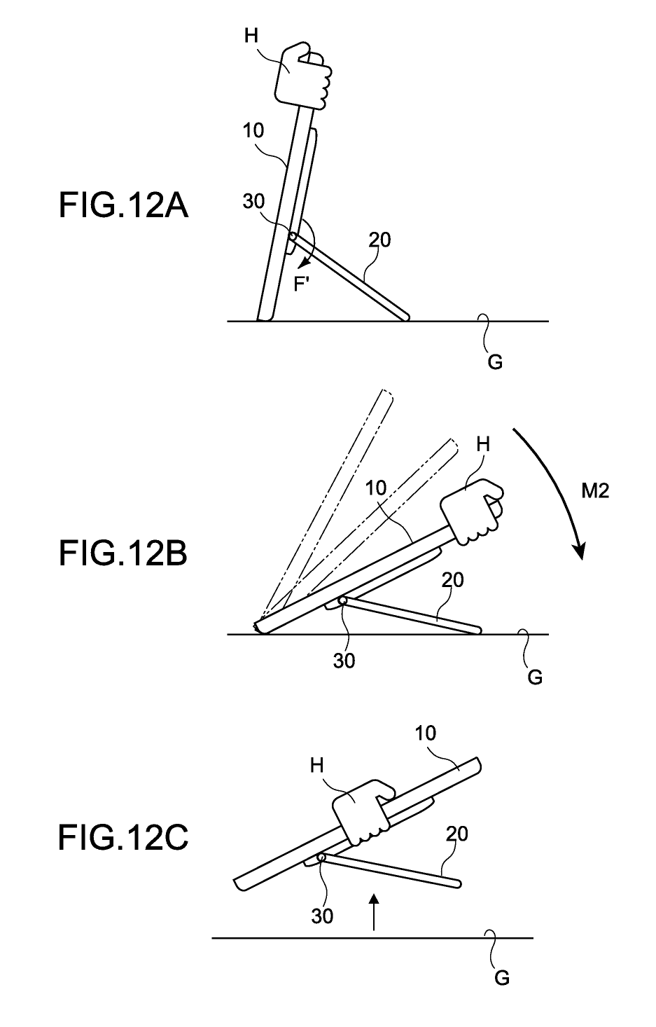

FIGS. 11A to 11C and FIGS. 12A to 12C are schematic side views illustrating other action example of the electronic apparatus according this embodiment.

In this embodiment, the adjustment mechanism 34 regulates the rotational force by the hinge unit 30 so that a relative position of the stand member 20 against the main body 10 can be held. Specifically, the hinge unit 30 is configured such that the nut member 342 is further fastened to decrease the rotational force acting on the stand member 20 lower than the above-described embodiment.

In this case, the stand member 20 does not rotate against the main unit 20 by the rotational force by the hinge unit 30. When the main body 10 is disposed on the put-on surface G, the main body 10 is disposed on the put-on surface G via the first support S1, and the stand member 20 is rotated from the second rotational position to a desired angle, as shown in FIGS. 11A to 11D.

According to this embodiment, as the rotational force F by the hinge unit 30 acts on the stand member 20 when the stand member 20 is rotated, a rotational operation force of the stand member 20 is decreased and the operability of the stand member 20 can be improved.

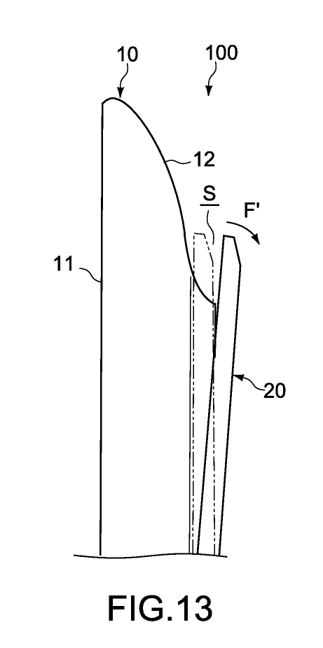

In this embodiment, the adjustment mechanism 34 may be configured to cancel a regulation of a rotational force F′ in a predetermined angle range from the second rotational position to the first rotational position of the stand member 20. In this case, as shown in FIG. 13, a predetermined space S is formed between the back surface 12 of the main body 10 and the stand member 20. The user's hand or finger is easily entered into the space S, and the operability of the stand member 20 can be improved.

The above-described operation is also applied to increase the tilt angle of the main body 10. In contrast, when the tilt angle of the main body 10 is decreased, the main body 10 may be pushed down to the put-on surface G, as in the above-described embodiment (FIGS. 12A and 12B). Again, the stand member 20 may be rotated to a desired angle position, and may be kept at a desired rotational position by the rotational force F′ by the hinge unit 30.

Further in this embodiment, as the rotational force F′ by the hinge unit 30 is regulated so that the relative position of the stand member 20 against the main body 10 can be held. As shown in FIG. 12C, the main body 10 can be translocated to other put-on surface while the tilt angle of the display surface D is kept. Therefore, a new setting of the tilt angle to the display surface D is unnecessary.

While the embodiments of the present technology are described herein, it should be understood that the present technology is not limited to the above-described embodiments, and variations and modifications may be made without departing from the scope and the spirits of the present technology.

For example, while the electronic apparatus 100 is described as information processing apparatus having a built-in display in the above-described embodiment, the present technology is not limited thereto and is applicable to a single monitor and other electronic apparatus having a display surface such as a television set.

While the main body 10 is described to include the convex part 120 on the back surface 12 in the above-described embodiment, the convex part 120 may be omitted depending on the specification. In addition, the back surface 12 may have not only a curve surface, but also a flat surface.

The stand member 20 is composed of a single member in the above-described embodiment, but may be composed of a plurality of members. In addition, the stand member 20 may have not only a curve surface, but also other geometric surface such as T-shaped and L-shaped surfaces.

Furthermore, while the hinge units 30 having the same configuration are disposed at the respective assisting arms 22 of the stand member 20 in the above-described embodiment, the hinge unit according to the present technology may instead be applied to either one of the arms and an existing hinge part may be applied to the other arm.

The present disclosure may have the following configurations.

(1) An electronic apparatus including:

a main body having a first surface having a display surface, a second surface opposite to the first surface, and a first support disposed between the first surface and the second surface being capable of contacting with a put-on surface;

a stand member attached to the main body having a second support being capable of contacting with the put-on surface; and

a hinge unit having a hinge rotatably supporting the stand member against the main body between a first rotational position for standing up the main body on the put-on surface and a second rotational position for laying the main body over the put-on surface, and an elastic member disposed at the hinge for adding a rotational force from a second rotational position side to a first rotational position side.

(2) The electronic apparatus according to (1) above, in which

the hinge unit further has an adjustment mechanism being capable of setting the rotational force, and

the adjustment mechanism is set to balance with a rotational moment by its own weight of the main body using the first support as a center.

(3) The electronic apparatus according to (2) above, in which

the adjustment mechanism regulates the rotational force so that a relative position of the stand member against the main body is held.

(4) The electronic apparatus according to (3) above, in which

the adjustment mechanism cancels a regulation of the rotational force in a predetermined angle range from the second rotational position to the first rotational position.

(5) The electronic apparatus according to any one of (1) to (4) above, in which

the elastic member has a torsion spring.

(6) The electronic apparatus according to any one of (1) to (5) above, in which

the hinge unit is disposed at the second surface.

(7) The electronic apparatus according to any one of (1) to (6) above, in which

the hinge unit is disposed nearer the first support side than a center position of the main body in a height direction.

(8) The electronic apparatus according to any one of (1) to (7) above, in which

the second surface has a convex part that is protruded from the main body outwardly, and

the convex part has a third support being capable of contacting with the put-on surface when the stand member is rotated to the second rotational position.

(9) The electronic apparatus according to (8) above, in which

the stand member has an arm that is bent along a circumference of the convex part at the second rotational position.

(10) The electronic apparatus according to (9) above, in which

the convex part has a surrounding part that is tapered to a center top of the convex part, and

the arm faces to the surrounding part and has a tapered inner peripheral part corresponding to the surrounding part.

(11) The electronic apparatus according to any one of (1) to (10) above, in which

the first support is disposed at the surrounding part of the main body, and

the surrounding part is formed of a flat or curve tilted surface.

The present disclosure contains subject matter related to that disclosed in Japanese Priority Patent Application JP 2012-188809 filed in the Japan Patent Office on Aug. 29, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic apparatus comprising:
a main body having a first surface having a display surface, a second surface opposite to the first surface, and a first support disposed between the first surface and the second surface being capable of contacting with a put-on surface;
a stand member attached to the main body having a second support being capable of contacting with the put-on surface; and
a hinge unit having a hinge rotatably supporting the stand member against the main body between a first rotational position for standing up the main body on the put-on surface and a second rotational position for laying the main body over the put-on surface, and an elastic member disposed at the hinge for adding a rotational force from a second rotational position side to a first rotational position side.

2. The electronic apparatus according to claim 1, wherein
the hinge unit further has an adjustment mechanism being capable of setting the rotational force, and
the adjustment mechanism is set to balance with a rotational moment by its own weight of the main body using the first support as a center.

3. The electronic apparatus according to claim 2, wherein
the adjustment mechanism regulates the rotational force so that a relative position of the stand member against the main body is held.

4. The electronic apparatus according to claim 3, wherein
the adjustment mechanism cancels a regulation of the rotational force in a predetermined angle range from the second rotational position to the first rotational position.

5. The electronic apparatus according to claim 1, wherein
the elastic member has a torsion spring.

6. The electronic apparatus according to claim 1, wherein
the hinge unit is disposed at the second surface.

7. The electronic apparatus according to claim 1, wherein
the hinge unit is disposed nearer the first support side than a center position of the main body in a height direction.

8. The electronic apparatus according to claim 1, wherein
the second surface has a convex part that is protruded from the main body outwardly, and
the convex part has a third support being capable of contacting with the put-on surface when the stand member is rotated to the second rotational position.

9. The electronic apparatus according to claim 8, wherein
the stand member has an arm that is bent along a circumference of the convex part at the second rotational position.

10. The electronic apparatus according to claim 9, wherein
the convex part has a surrounding part that is tapered to a center top of the convex part, and
the arm faces to the surrounding part and has a tapered inner peripheral part corresponding to the surrounding part.

11. The electronic apparatus according to claim 1, wherein
the first support is disposed at the surrounding part of the main body, and
the surrounding part is formed of a flat or curve tilted surface.
